(19) United States
(12) Patent Application Publication
(10) Pub. No.: US 2011/0127676 A1
(43) Pub. Date: Jun. 2, 2011

(54) Lead pin for semiconductor package and semiconductor package

(75) Inventors: Jin Won Choi, Yongin (KR); Seung Jean Moon, Suwon (KR); Ki Taek Lee, Seoul (KR)

(73) Assignee: SAMSUNG ELECTRO-MECHANICS CO., LTD., Suwon (KR)

(21) Appl. No.: 12/805,295

(22) Filed: Jul. 22, 2010

(30) Foreign Application Priority Data
Nov. 27, 2009 (KR) 10-2009-0115491

(51) Int. Cl. H01L 23/48; H01B 5/00

(52) U.S. Cl. 257/773; 174/126.1; 257/E23.01

(57) ABSTRACT

Disclosed is a lead pin for a semiconductor package. The lead pin includes a coupling pin inserted into a hole formed in an external device, a head portion disposed at one end of the coupling pin, and a step portion formed in a stepped manner between the coupling pin and the head portion, the step portion having a smaller size than the head portion.

### CROSS-REFERENCE TO RELATED APPLICATIONS

This application claims the priority of Korean Patent Application No. 10-2009-0115491 filed on Nov. 27, 2009, in the Korean Intellectual. Property Office, the disclosure of which is incorporated herein by reference.

### BACKGROUND OF THE INVENTION

1. Field of the Invention

The present invention relates to a lead pin for a semiconductor package, and a semiconductor package, and more particularly, to a lead pin for connecting a package substrate, including an integrated circuit (IC) thereon, to a main board, and a semiconductor package including the same.

2. Description of the Related Art

As the electronics industry has developed, various types of semiconductor package have been manufactured. As interconnections for semiconductor packages have become highly dense, a Pin Grid Array (PGA) semiconductor package substrate on which a plurality of T-type lead pins are installed is widely used as a substrate which connects a package substrate, on which an IC is mounted, to a main board.

A typical package substrate generally uses an insertion-type pin, which is inserted into a through-hole, and a T-type lead pin, which is attached to a package substrate by soldering. Compared with the insertion-type pin, the T-type lead pin is commonly used because there is less limitation on the circuit configuration of the package substrate.

Since the use of Pb has recently been restricted due to consideration of the environmental impact of soldering, a Pb-free solder such as Sn—Ag—Cu or Sn—Sb is used. Thus, a solder melting temperature is high.

As the solder melting temperature increases, a solder which supports a lead pin may be melted by reflow heat during a reflow process for mounting an IC chip on a package substrate, causing the lead pin to be inclined.

Furthermore, a solder often flows over the lead pin and then flows toward the coupling pin during the reflow process. Therefore, there is a need for technologies which can solve these problems.

### SUMMARY OF THE INVENTION

An aspect of the present invention provides a lead pin for a semiconductor package, which prevents a coupling pin from being contaminated by a solder paste and achieves enhanced bonding efficiency by increasing a contact area between a head portion and the solder paste.

According to an aspect of the present invention, there is provided a lead pin for a semiconductor package, the lead pin including: a coupling pin inserted into a hole formed in an external device; a head portion disposed at one end of the coupling pin; and a step portion formed in a stepped manner between the coupling pin and the head portion, the step portion having a smaller size than the head portion.

The step portion of the lead pin may have a circular shape.

The step portion of the lead pin may include a protrusion protruding from an edge thereof.

The step portion of the lead pin may have a greater diameter on one side of the step portion than that on the other side thereof located at an interface between the step portion and the head portion.

The head portion of the lead pin may include: a flange section disposed at the one end of the coupling pin and having a disc shape; and a round section disposed on a top surface of the flange section and having a dome shape, the round section having a smaller area than the flange section.

The head portion of the lead pin includes: a flange section disposed at the one end of the coupling pin and having a disc shape; and a round section having a dome shape and disposed on a top surface of the flange section, the round section having the same diameter as that of the top surface of the flange section at an interface between the round section and the top surface of the flange section.

According to another aspect of the present invention, there is provided a semiconductor package including: a substrate having a pad on one surface thereof; and a lead pin including a coupling pin inserted into a hole formed in an external device, a head portion disposed at one end of the coupling pin, and a step portion formed in a stepped manner between the coupling pin and the head portion, the step portion having a smaller size than the head portion.

The step portion of the semiconductor package may have a circular shape.

The step portion of the semiconductor package may include a protrusion protruding from an edge thereof.

The step portion of the semiconductor package may be inclined toward an interface between the step portion and the head portion.

The head portion of the semiconductor package may include: a flange section disposed at the one end of the coupling pin and having a disc shape; and a round section having a dome shape and disposed on a top surface of the flange section, the round section having a smaller area than the flange section.

The head portion of the semiconductor package may include: a flange section disposed at the one end of the coupling pin and having a disc shape; and a round section having a dome shape and disposed on a top surface of the flange section, the round section having the same diameter as that of the top surface of the flange section at an interface between the round section and the top surface of the flange section.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a semiconductor package according to an exemplary embodiment of the present invention;

FIG. 2 is a cross-sectional view illustrating how a lead pin, depicted in FIG. 1, is mounted on a substrate;

FIG. 3A is a plan view illustrating the lead pin depicted in FIG. 1;

FIG. 3B is a bottom view illustrating the lead pin depicted in FIG. 1;

FIG. 4 is a cross-sectional view illustrating a lead pin according to another exemplary embodiment of the present invention;

FIG. 5 is a cross-sectional view illustrating a lead pin according to another exemplary embodiment of the present invention; and

FIG. 6 is a cross-sectional view illustrating a lead pin according to another exemplary embodiment of the present invention.

### DETAILED DESCRIPTION OF THE PREFERRED EMBODIMENT

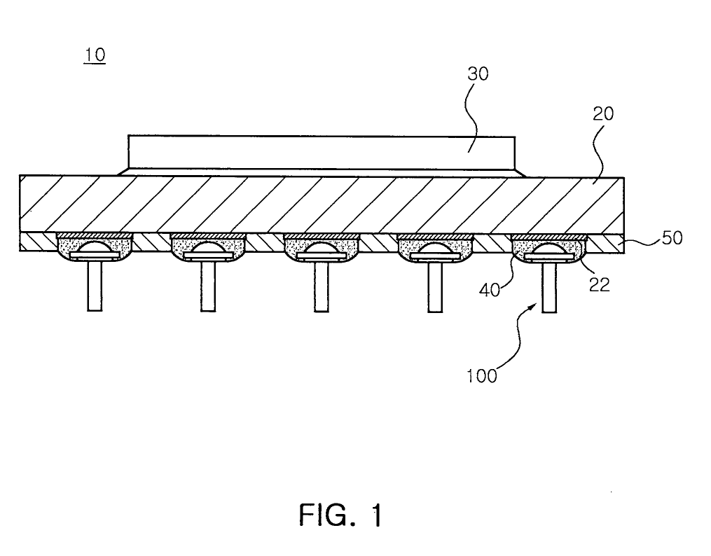

A semiconductor package and a lead pin thereof, according to exemplary embodiments of the present invention, will now be described in greater detail with reference to FIGS. 1 through 6.

Exemplary embodiments of the present invention will now be described in detail with reference to the accompanying drawings. The invention may, however, be embodied in many different forms and should not be construed as being limited to the embodiments set forth herein. While those skilled in the art could readily devise many other varied embodiments that incorporate the teachings of the present invention through the addition, modification or deletion of elements, such embodiments may fall within the scope of the present invention.

The same or equivalent elements are referred to as the same reference numerals throughout the specification.

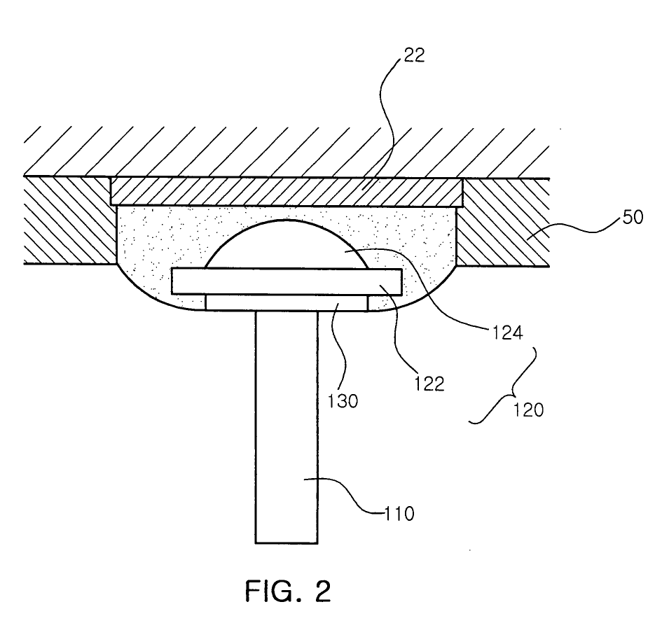

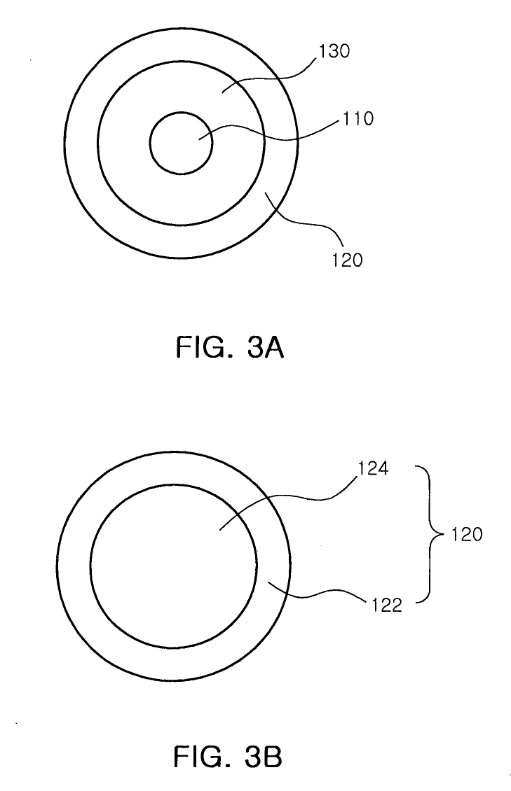

FIG. 1 is a cross-sectional view illustrating a semiconductor package according to an exemplary embodiment of the present invention, FIG. 2 is a cross-sectional view illustrating how a lead pin, depicted in FIG. 1, is mounted on a substrate, FIG. 3A is a plan view illustrating the lead pin depicted in FIG. 1, and FIG. 3B is a bottom view illustrating the lead pin depicted in FIG. 1.

Referring to FIGS. 1 through 3B, a semiconductor package 10 may include a substrate 20 and lead pins 100.

A semiconductor chip 30 is electrically connected to the surface of the substrate 20. The substrate 20 may be an organic board or a ceramic board utilizing low temperature co-fired ceramics (LTCC) for example.

In addition, pads 22 may be formed on the bottom of the substrate 20 and electrically connected with the respective lead pins 100. A photoresist layer 50 may be provided around the pads 20. Here, the substrate 20 may have a multilayer structure. In this case, the substrate 20 may include circuit patterns for electrically connecting multiple layers therein.

The semiconductor package 10 is mounted such that the semiconductor chip 30 is electrically connected to the substrate 20, thereby achieving a reduction in the size thereof.

The lead pins 100 are electrically connected to the pads 20, formed on the bottom surface of the substrate 20, by using a solder paste 40. The lead pins 100 each include a coupling pin 110, a head portion 120, and a step portion 130.

The coupling pin 110 is a portion inserted into a socket or the like when the lead pin 100 is mounted on a package substrate. This coupling pin 110 may have a cylindrical shape having a predetermined length according to a kind of package substrate. The lead pin 100 is mounted such that the coupling pin 110 protrudes above the substrate 20.

The coupling pin 110 is connected to the end of the head portion 120. In this case, the head portion 120 and the coupling pin 110 may be formed concentrically.

In this case, the coupling pin 110 and the head portion 120 may be integrated with each other and formed of the same material, which is a conductive metal. However, the material of the lead pin 100 is not limited to the above described material.

As stated above, the head portion 120 is formed integrally with the coupling pin 110 and electrically connected to the substrate 20 (i.e., a package substrate) by the solder paste 40 applied on the exposed portion of the pad 22 of the substrate 20.

Further, the head portion 120 is formed at one end of the coupling pin 110, and includes a flange section 122 having a disc shape and a round section 124 having a dome shape. The flange section 122 and the round section 124 are formed successively. Here, the head portion 120 is mounted such that the dome-shaped round section 124 contacts the pad 22 of the substrate 20.

In this case, the diameter of the flange section 122 may be greater than that of the round section 124 protruding on the top surface of the flange section 122 in the form of a dome (hemisphere). When the head portion 120 is bonded with the pad 22, the solder paste 40 flows into the space between the top surface of the flange section 122 and the outer circumferential surface of the round section 124. At this time, the above-described difference in diameter therebetween is contributive to preventing the solder paste 40 from undesirably flowing onto the bottom surface of the flange section 122.

The round section 124 may be characterized in that a portion of the round section 124 corresponding to the diameter of the coupling pin 110 has a curvature that is equal to or greater than the curvature of the edge of the round section 124. The round section 124 is not limited to the description and may have the same curvature in every portion.

In this respect, the round section 124 may have a central portion having a slope gentler than that of its edge. This round section 124 may prevent the tilting of the lead pin 100. The structure of the round section 124 having the above-described radius of curvature may cause air bubbles to flow out from the solder paste 40.

The flange section 122 and the round section 124 forming the head portion 120 may have different respective heights. The central height of the round section 124 having a predetermined curvature may be greater than the height of the flange section 122.

By rendering the central height of the round section 124 greater than the height of the flange section 122, a contact area between the curved surface of the round section 124 and the solder paste 40, surrounding the head portion 120, can be increased within the design space of the head portion 120, when the head portion 120 is mounted on the substrate 20.

Accordingly, the coupling pin 110 can be vertically installed without being tilted on the substrate 20. Moreover, the increased contact area may improve bonding performance.

Here, the solder paste 40 is formed of an alloy of lead, zinc and silver (i.e., a Pb/Zn/Ag alloy). When heat is applied to the solder paste 40, the solder paste 40 is melted into a viscous liquid phase. Then, the solder paste 40 is hardened in the shape of the melted state by cooling at room temperature, and bonded with a target object in the hardened state.

As shown in FIG. 3A, the step portion 130 may be formed between the coupling pin 110 and the head portion 120. In this case, the size of the step portion 130 is smaller than the diameter of the flange section 122. This difference in size causes the edge of the step portion 130 to be stepped with relation to the edge of the flange section 122.

Here, like the head portion 120, the step portion 130 may also be formed integrally with the coupling pin 110. However, the present invention is not limited to this structure.

According to this exemplary embodiment of the present invention, the step portion 130 between the coupling pin 110 and the head portion 120 blocks the flow of the solder paste toward the coupling pin 110, thereby preventing the contamination of the coupling pin 110.

Further, according to this exemplary embodiment, the contact area is increased by the step portion 130, thereby enhancing bonding efficiency.

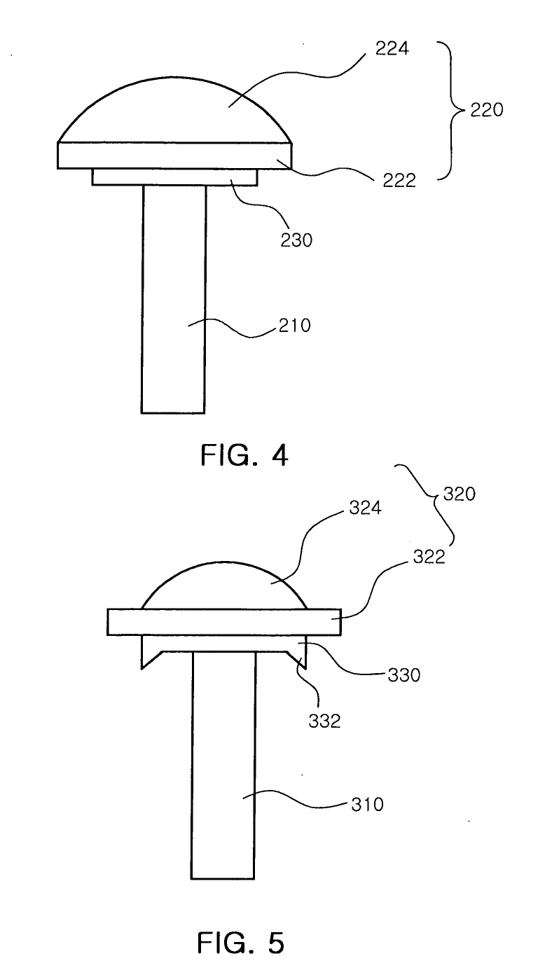

FIG. 4 is a cross-sectional view illustrating a lead pin according to another exemplary embodiment of the present invention.

Referring to FIG. 4, the lead pin may include a coupling pin 210, a head portion 220 and a step portion 230.

Here, the coupling pin 210 and the step portion 230, according to this exemplary embodiment of the present invention, are substantially the same as those of the previous embodiment. Therefore, a detailed description thereof may be omitted. The head portion 220 includes a flange section 222 and a round section 224. Here, the round section 224 may have the same diameter as that of the top surface of the flange section 222 at the interface between the round section 224 and the top surface of the flange section 222.

The head portion 220 includes a flange section 222 and a round section 224 having a dome shape. The diameter of the flange section 222 may be greater than that of the round section 224, which protrudes on the top surface of the flange section 222 in the form of a dome. Accordingly, the shape of the head portion 220 may be freely determined according to a designer's intention.

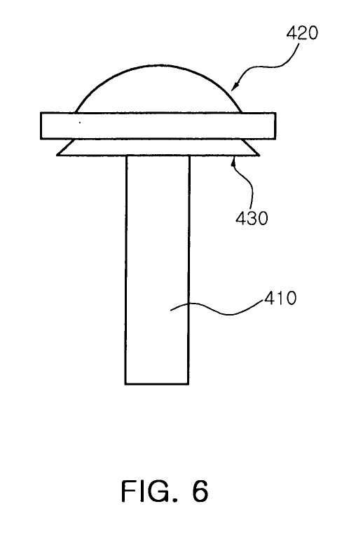

FIG. 5 is a cross-sectional view illustrating a lead pin according to another exemplary embodiment of the present invention. FIG. 6 is a cross-sectional view illustrating a lead pin according to another exemplary embodiment of the present invention.

Referring to FIG. 5, a step portion 330 is formed between a coupling pin 310 and a head portion 320. The diameter of the step portion 330 is smaller than the diameter of the flange section 322. This difference in size causes the edges of the flange section 322 and the step portion 330 to be stepped with relation to each other.

In this case, the step portion 330 may have protrusions 332 protruding downwards from both edges thereof. The protrusions 332 each may be tapered in an outer circumferential direction of the flange section 322. This allows the protrusion 322 to be more deeply embedded into the solder paste 40, thereby enhancing adhesive force.

Referring to FIG. 6, a step portion 430 is formed between a coupling pin 410 and a head portion 420. Here, the step portion 430 may be formed such that one side thereof adjacent to the interface between the step portion 430 and the head portion 420 has a smaller diameter than the other side thereof.

According to this exemplary embodiment, the diameter of the step portion 430 gradually increases from the one side portion, located at the interface between the step portion 430 and the head portion 420, toward the other side thereof.

Since the step portion 430, formed between the coupling pin 410 and the head portion 420, blocks the flow of the solder paste toward the coupling pin 410, the contamination of the coupling pin 410 can be prevented. Furthermore, the other side of the step portion 430, having a greater diameter than the one side, is deeply embedded into the solder paste, thereby enhancing adhesive force.

As set forth above, in the lead pin for a semiconductor package and the semiconductor package according to exemplary embodiments of the invention, the step portion, having a smaller size than the head portion, is formed in a stepped manner between the coupling pin and the head portion. Thus, when the head portion is mounted on a package, the step portion prevents a solder resist from undesirably flowing over the head portion, so that the contamination of the coupling pin can be prevented. In addition, the step portion increases a contact area between the head portion and the solder resist, thereby enhancing bonding efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A lead pin for a semiconductor package, the lead pin comprising:
a coupling pin inserted into a hole formed in an external device;
a head portion disposed at one end of the coupling pin; and
a step portion formed in a stepped manner between the coupling pin and the head portion, the step portion having a smaller size than the head portion.

2. The lead pin of claim 1, wherein the step portion has a circular shape.

3. The lead pin of claim 1, wherein the step portion includes a protrusion protruding from an edge thereof.

4. The lead pin of claim 1, wherein the step portion has a greater diameter on one side of the step portion than on the other side thereof located at an interface between the step portion and the head portion.

5. The lead pin of claim 1, wherein the head portion includes:
a flange section disposed at the one end of the coupling pin and having a disc shape; and
a round section disposed on a top surface of the flange section and having a dome shape, the round section having a smaller area than the flange section.

6. The lead pin of claim 6, wherein the head portion includes:
a flange section disposed at the one end of the coupling pin and having a disc shape; and
a round section having a dome shape and disposed on a top surface of the flange section, the round section having the same diameter as that of the top surface of the flange section at an interface between the round section and the top surface of the flange section.

7. A semiconductor package comprising:
a substrate having a pad on one surface thereof; and
a lead pin including a coupling pin inserted into a hole formed in an external device, a head portion disposed at one end of the coupling pin, and a step portion formed in a stepped manner between the coupling pin and the head portion, the step portion having a smaller size than the head portion.

8. The semiconductor package of claim 7, wherein the step portion has a circular shape.

9. The semiconductor package of claim 7, wherein the step portion includes a protrusion protruding from an edge thereof.

10. The semiconductor package of claim 7, wherein the step portion is inclined toward an interface between the step portion and the head portion.

11. The semiconductor package of claim 7, wherein the head portion includes:
a flange section disposed at the one end of the coupling pin and having a disc shape; and
a round section having a dome shape and disposed on a top surface of the flange section, the round section having a smaller area than the flange section.

12. The semiconductor package of claim 7, wherein the head portion includes:
a flange section disposed at the one end of the coupling pin and having a disc shape; and
a round section having a dome shape and disposed on a top surface of the flange section, the round section having the same diameter as that of the top surface of the flange section at an interface between the round section and the top surface of the flange section.
